(19) United States
(12) Patent Application Publication
(10) Pub. No.: US 2004/0153945 A1
(43) Pub. Date: Aug. 5, 2004

(54) Error correction circuit employing cyclic code

(76) Inventor: Isao Takami, Tokyo (JP)

Correspondence Address: VOLENTINE FRANCOS, PLLC, Suite 150, 12200 Sunrise Valley Drive, Reston, VA, 20191, US

(21) Appl. No.: 10/631,734

(22) Filed: Aug. 1, 2003

(30) Foreign Application Priority Data
Nov. 22, 2002 (JP) 2002-339659

(51) Int. Cl. H03M 13/00

(52) U.S. Cl. 714/758

(57) ABSTRACT

An error correction circuit employing the cyclic code quickly corrects a single error contained in a received codeword. A serial-to-parallel converter converts the received codeword from serial data to parallel data. A CRC calculator divides the received codeword by a generator polynomial to output the remainder to logical gates. The logical gates determine to which of the remainder patterns, previously calculated for each location of the received codeword containing a single error, in which a single error is located, correspond to the remainder patterns output from the CRC calculator, and detects a location containing the single error. The logical gates set detection signals corresponding to the single error location to 1. An exclusive OR gate executes an exclusive OR operation on the received codeword output from the serial-to-parallel converter and the detection signal output from the logical circuits, on the bit basis, to correct the single error contained in the received codeword.

### BACKGROUND OF THE INVENTION

1. Field of the Invention

The present invention relates to an error correction circuit employing a cyclic code.

2. Description of the Background Art

The signal transmitted over a transmission channel contains errors frequently. Among known methods for detecting such errors, there is a CRC (cyclic redundancy check) error detection method, employing a cyclic code. This error detection method detects code errors in a fashion read as follows: With a received polynomial Y x), a generator polynomial G(x), a remainder polynomial S(x), a code polynomial W(x) and an error polynomial E(x), the remainder S(x), obtained on dividing Y(x) by G(x), is

S(x)=Y(x) mod G(x). (1)

Supposing the degree of the polynomial G(x) is m or less, the degree of the polynomial S(x) is (m−1) or less. Since Y(x)={W(x)+E(x)},the expression (1) may be rewritten to the following form.

S(x)={W(x)+E(x)} mod G(x) (2)

Since W(x) is generated so as to be completely divisible by G(x), the expression (2) may be rewritten to the following form.

S(x)=E(x) mod G(x) (3)

The remainder polynomial S(x), termed a syndrome polynomial, is not affected by the code polynomial W(x) but is determined solely by the error polynomial E(x), as may be understood from the expression (3). For error detection, it is sufficient to check whether or not the polynomial S(x) calculated on a received codeword is coincident with the polynomial S(x) previously calculated on an error-free codeword. For error correction, it is sufficient that the polynomial S(x) calculated on a received codeword is compared with the polynomial S(x) previously calculated on a codeword for each degree containing an error to identify the degree in which an error has occurred to correct the error.

Heretofore, in an error correcting circuit of a radio communication equipment, disclosed in e.g. Japanese patent laid-open publication No. 221718/1995, the remainders for received codes, corrupted with errors, are calculated at the outset, the results of remainder calculations and bit locations indicating the error locations are provided in the form of table data, the results of remainder calculations coincident with those calculated for actually received codes are retrieved from the table data and the bit of the error bit location corresponding to the coincident results of remainder calculations is corrected.

This error correction circuit is primarily aimed to find the error bit location, and the received code is corrected for error based on the error bit location of the received code specified using table data. Thus, the error correction circuit suffers from a problem that the circuit is not efficient in an application in which the primary object is to correct the error. It is because the bit position data indicating the error bit location is not particularly required in a case where correction of the received code is the primary object.

Moreover, the above-described conventional error correction circuit suffers from a problem that the operation of locating an error bit of the received code is time-consuming since it is necessary to compare the remainder data obtained on remainder calculations of the received code using the generator polynomial sequentially with the results of the remainder calculations of the table data. Since the table data are composed of the results from the remainder calculations for the totality of the codes upon one-bit errors, the table data become voluminous when the length of the received code is increased. For example, if the code length of a received code is 196 bits, 196 entries in the table data are needed, such that the operation of sequential comparison with the table data becomes extremely time-consuming.

### SUMMARY OF THE INVENTION

It is an object of the present invention to provide an error correction circuit employing the cyclic code in which the above-described shortcomings of the related art may be overcome and the time needed for error correction may be reduced appreciably.

For accomplishing the above object, the present invention provides an error correction circuit of the cyclic code system comprising a CRC calculator for calculating the remainder of a received codeword in accordance with the CRC system, an error location detector for detecting the location of a single error contained in the received codeword, based on a first remainder pattern calculated by the CRC calculator, and an error bit corrector for correcting a bit of the received codeword, lying at a location detected by the error location detector.

In accordance with the present invention, there is provided the CRC calculator and the error location detector for detecting the error position by checking the syndrome in the case of a single error. When the CRC calculator finds out the syndrome, the error location detector can detect the error location corresponding to the syndrome extremely readily, so that error correction can be executed speedily.

### BRIEF DESCRIPTION OF THE DRAWINGS

The objects and features of the present invention will become more apparent from consideration of the following detailed description taken in conjunction with the accompanying drawings in which:

FIG. 1 is a block diagram schematically showing a preferred embodiment of an error correction circuit according to the present invention;

FIG. 2 shows the bit array of the (7,4) Hamming code;

FIG. 3 is a schematic block diagram showing an example of a CRC calculator in the error correction circuit of FIG. 1; and

FIG. 4 shows the remainder output from the CRC calculator in the error correction circuit of FIG. 1.

### DESCRIPTION OF THE PREFERRED EMBODIMENT

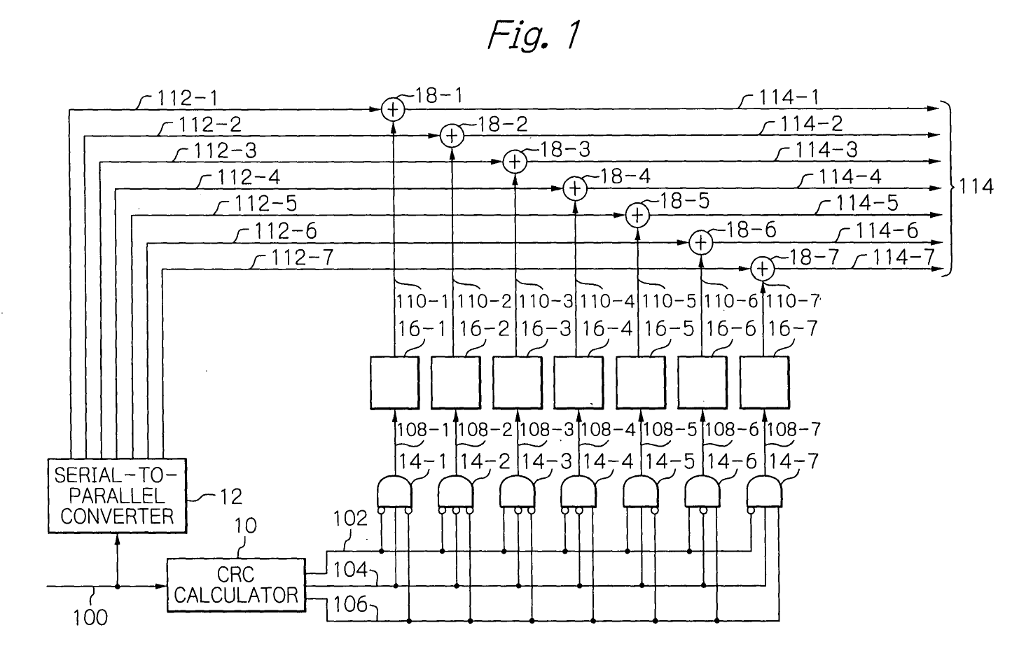

With reference to FIG. 1, a preferred embodiment of the error correction circuit employing the cyclic code according to the present invention is explained in detail. This error correction circuit shows an example in which a received signal 100 is of the (7,4) Hamming code. The correction circuit includes a CRC calculator 10, a serial-to-parallel converter 12, logical gates 14-1 to 14-7, registers 16-1 to 16-7 and exclusive OR gates 18-1 to 18-7. It is noted that symbols affixed to connection lines indicate signals present on the connection lines.

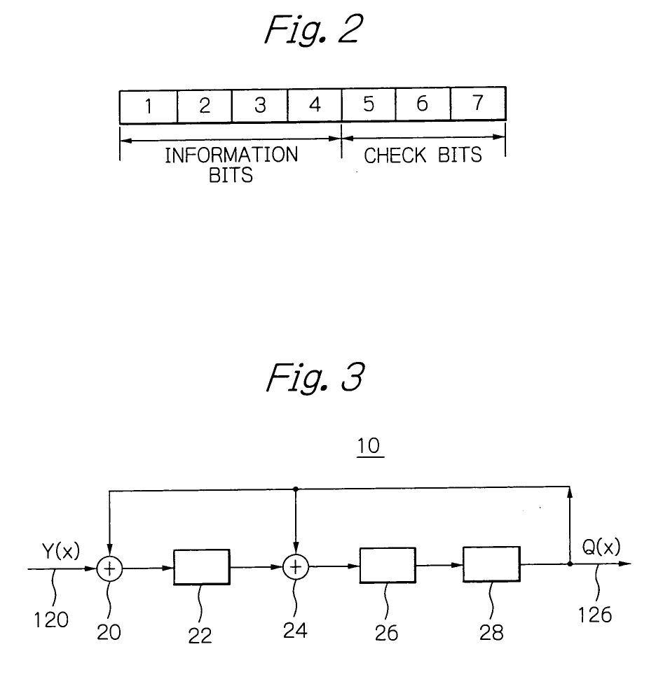

A received codeword 100 is of (7,4) Hamming code. FIG. 2 shows the (7,4) Hamming code that is made up by information bits (bits 1 to 4) and check bits (bits 5 to 7). The received codeword 100 is serially input to the CRC calculator 10 and to the serial to parallel converter 12 in the order of from bit 1 to bit 7. If the received code 100 is in the form of parallel data, it is sufficient to provide a parallel-to-serial converter, converting the parallel data to serial data, on an input side of the error correction circuit, and to input an output of this parallel-to-serial converter to the CRC calculator 10 and to the serial-to-parallel converter 12.

The CRC calculator 10 is adapted for calculating the remainder of the received codeword 100 in accordance with the CRC system. Specifically, the CRC calculator is implemented by a division circuit for dividing a received polynomial Y (x), which represents the received codeword 100, by a cubic generator polynomial G (x) (=x³+x+1) to output signals 102, 104 and 106 that represent remainder of the division.

FIG. 3 is a block diagram showing an illustrative structure of the CRC calculator 10. This CRC calculator 10 is a routine division circuit, made up by exclusive OR gates 20 and 24 and flip-flops 22, 26 and 28. When a received codeword 120 is input to the exclusive OR gate 20, the flip-flop 28 outputs a quotient of division. At a time point when the last bit of the received codeword 120 is input to the exclusive OR gate 20, the calculations in the exclusive OR gates 20 and 24 are finished and the flip-flops 22, 26 and 28 are updated, the contents R1, R2 and R3 of the flip-flops 22, 26 and 28 represent the remainder of the division.

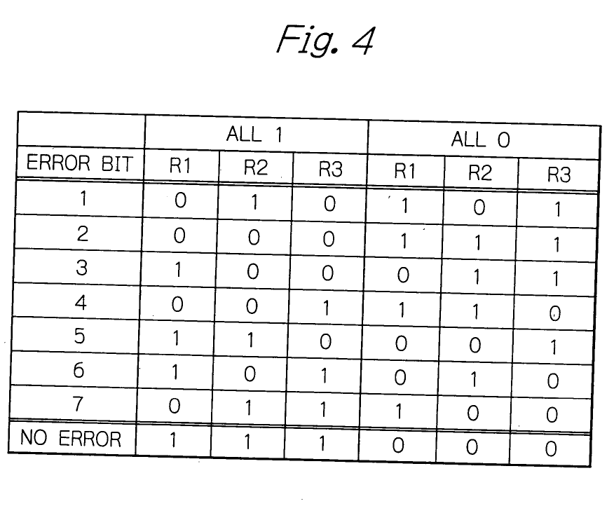

FIG. 4 shows values of R1 to R3 when an error-free received codeword 100 or a received codeword 100 containing an error in one of bits 1 to 7 is input to the CRC calculator 10. Meanwhile, [ALL 1] and [ALL 0] in FIG. 4 denote values of R1 to R3 when the initial values of flip-flops in the CRC calculator 10 corresponding to the flip-flops 22, 26, 28 of FIG. 3 are all set to binary 1 and 0, respectively. For example, if the initial values are ALL 1, the values (R1, R2, R3) for the received codeword 100 containing an error in the bit 1 are (0, 1, 0).

Meanwhile, the values R1 to R3 represent coefficients of a remainder polynomial S(x). The remainder polynomial S(x) is the remainder obtained when an error polynomial E(x) is divided by the division circuit of FIG. 3, as may be seen from the above expression (3), and represents a remainder for an error polynomial E (x) containing a single error. In the case of a code with a Hamming distance of not less than 3, the remainder in the case a single error is contained in a certain degree is necessarily different from the remainder when a single error is contained in another degree. In FIG. 4, a set of values (R1, R2, R3) differs from one error location to another. Thus, if the remainder is found in advance for each error location, an error location corresponding to the remainder of the input received codeword can be identified extremely readily.

The logical gates 14-1 to 14-7, connected to the CRC calculator 10, form pattern detection circuits for detecting the patterns (R1, R2, R3) by executing logical operations on signals 102, 104 and 106 output from the CRC calculator 10. The patterns detected are prefixed from one logical gate to another. For example, the logical gates 14-1 and 14-2 detect the patterns (0, 1, 0) and (0, 0, 0), respectively. In this case, the error location in the received codeword 100 has a one-to-one correspondence with the patterns, such that a group of the logical gates 14-1 to 14-7 may be said to be an error location detector for detecting the error location in the received codeword 100.

The logical gates 14-1 to 14-7 output the detected results in the form of detected signals 108-1 to 108-7. In the present embodiment, each of the detected signals 108-1 to 108-7 is set to 1 or 0 when the pattern has been detected or not, respectively. In the embodiment, the logical gates 14-1 to 14-7 are specifically adapted to detect the patterns of (R1, R2, R3) when the flip-flops in the CRC calculator 10 are set to 1.

The registers 16-1 to 16-7, connected to the logical gates 14-1 to 14-7, respectively, contain flip-flops for temporarily holding the detected signals 108-1 to 108-7 output from the logical gates 14-1 to 14-7, and set the outputs 110-1 to 110-7 thereof to 1 or 0 when the detected signals 108-1 to 108-7 are 1 or 0, respectively. The serial-to-parallel converter 12 converts the received codeword 100 from serial data to parallel data to store in its internal register, not shown, and outputs bits 1 to 7 of the parallel data stored in the internal register, at the timing as commanded by a controller, also not shown, as signals 112-1 to 112-7, respectively.

The exclusive OR gates 18-1 to 18-7 have one input terminal connected to the serial-to-parallel converter 12, and the other input terminals thereof connected to the registers 16-1 to 16-7. The exclusive OR gates 18-1 to 18-7 correct error bits contained in the received codeword 100, and perform the exclusive OR operation on both signals 112-1 to 112-7 output from the serial-to-parallel converter 12 and signals 110-1 to 110-7 output from the registers 16-1 to 16-7 on the bit-by-bit basis, respectively.

For example, when an output 110-1 of the register 16-1 is 1, the exclusive OR gate 18-1 converts the output signal 112-1 of the serial-to-parallel converter 12 to 0 if the output signal 112-1 is 1, while converting the output signal 112-1 of the serial-to-parallel converter 12 to 1 if the output signal 112-1 is 0, and outputs the resulting signal, by way of error correction. However, when the output 110-1 of the register 16-1 is 0, the exclusive OR gate 18-1 outputs the signal 112-1 uncorrected. The remaining exclusive OR gates 18-2 to 18-7 operate in a similar manner. Thus, the exclusive OR gates 18-1 to 18-7 correct the bits of the error locations detected by the logical circuits 14-1 to 14-7, respectively. A group of the exclusive OR circuits 18-2 to 18-7 may be said to be an error bit corrector for correcting an error bit of the received codeword 100.

The error correction circuit of FIG. 1 operates as follows: The received codeword 100 is input to the CRC calculator 10 and to the serial-to-parallel converter 12. The serial-to-parallel converter 12 converts the received codeword 100, with a code length of 7 bits, from serial data to parallel data, and holds the resulting parallel data temporarily in its internal register. The serial-to-parallel converter 12 then outputs bits 1 to 7 of the received codeword 100, thus held, as signals 112-1 to 112-7, respectively. The signals 112-1 to 112-7 are input to the exclusive OR gates 18-1 to 18-7, respectively.

The CRC calculator 10 performs division on the received codeword 100 and, at a time point when the last bit of the received codeword 100 is input, outputs signals 102, 104, 106. The signals 102 to 106 are corresponding to R1 to R3 representing the remainder of division. Meanwhile, the patterns of R1 to R3 (R1, R2, R3) differ in dependence upon the location of the single error in the received codeword 100, as shown in FIG. 4. The signals 102 to 106 are input to the logical gates 14-1 to 14-7 in parallel.

The logical gates 14-1 to 14-7 execute logical operations, based on the signals 102, 104, 106, to detect the possible presence of the patterns (R1, R2, R3) that are defined specifically to the logical gates. If an error is contained in the n-th bit of the received codeword 100, where 1≦n≦7, the logical gate 14-n sets an output detection signal 108-n to 1, with the remaining logical gates setting the output detection signal outputs thereof to 0. If no error is contained in the received codeword 100, the entire logical circuits 14-1 to 14-7 set detection signals 108-1 to 108-7 to 0. The detection signals 108-1 to 108-7 are input to the registers 16-1 to 16-7.

The registers 16-1 to 16-7 temporarily hold the detection signals 108-1 to 108-7, output from the logical gates 14-1 to 14-7, to output the detection signals, thus held, as signals 110-1 to 110-7. When the detection signals 108-1 to 108-7 are 1 or 0, the signals 110-1 to 110-7 become 1 or 0, respectively. The signals 110-1 to 110-7 and the signals 112-1 to 112-7, output from the serial-to-parallel converter 12, are input to the exclusive OR gates 18-1 to 18-7, respectively, in timed relation to each other. The exclusive OR gates 18-1 to 18-7 perform the exclusive OR operation on both the signals 112-1 to 112-7 and the signals 110-1 to 110-7, on the bit-by-bit basis, to output the results of the operations as signals 114-1 to 114-7, respectively.

For example, if the received codeword 100, containing an error in the n-th bit, is input to the CRC calculator 10, the logical gate 14-n detects the pattern (R1, R2, R3) in the case of an error existing in the n-th bit, and sets the detection signal 108-n to 1, so that the output signal 110-n of the register 16-n is 1. The signal 110-n and the signal 112-n, which is the n-th bit of the received codeword 100 are input to the exclusive OR gate 18-n. Since the signal 110-n is 1, the exclusive OR gate 18-n corrects the signal 112-n to 0 or to 1, when the signal 112-n is 1 or 0, respectively, to output the resulting signal 114-n.

At this time, the logical gates other than the logical gate 14-n set the detection signals to 0. Thus, the output signals of the registers other than the register 16-n are all 0. Consequently, the exclusive OR gates other than the exclusive OR gate 18-n directly output the signals input from the serial-to-parallel converter 12. In this manner, the exclusive OR gates 18-1 to 18-7 correct errors contained in the received codeword 100 to output a corrected codeword 114 composed of the signals 114-1 to 114-7.

Although the present embodiment is directed to an error correction circuit employing the (7,4) Hamming code, the present invention may also be applied to any other cyclic code in which the Hamming distance is not less than 3. The present invention may, of course, be applied to such a case where the generator polynomial is a 16-bit generator polynomial recommended by the CCITT (Comit Consultatif Internationale Telegraphique et Telephonique). On the other hand, when the Hamming distance is not less than 5, double errors may also be corrected, to which case the present embodiment may be applied.

Moreover, when the received codeword 100 contains a single error, (R1, R2, R3), calculated by the CRC calculating unit 10, falls under one of (R1, R2, R3) shown in FIG. 4. However, if the received codeword 100 contains plural bit errors, a set of values (R1, R2, R3), calculated by the CRC calculating unit 10, does not fall under any of the (R1, R2, R3) shown in FIG. 4. Thus, by detecting whether or not the set of values (R1, R2, R3), calculated by the CRC calculating unit 10, falls under the (R1, R2, R3) shown in FIG. 4, it is possible to verify whether or not the error is of two or more bit errors.

The entire disclosure of Japanese patent application No. 2002-339659 filed on Nov. 22, 2002, including the specification, claims, accompanying drawings and abstract of the disclosure is incorporated herein by reference in its entirety.

While the present invention has been described with reference to the particular illustrative embodiment, it is not to be restricted by the embodiment. It is to be appreciated that those skilled in the art can change or modify the embodiment without departing from the scope and spirit of the present invention.

What is claimed is:

1. An error correction circuit, employing a cyclic code, comprising:
a CRC calculator for calculating a remainder of a received codeword in accordance with a CRC system;
an error location detector for detecting a location of a single error contained in the received codeword, based on a first remainder pattern calculated by said CRC calculator; and
an error bit corrector for correcting a bit of the received codeword, lying at a location detected by said error location detector.

2. The error correction circuit in accordance with claim 1, wherein said error location detector determines to which of second remainder patterns, previously calculated for each location of the received codeword containing a single error, in which the single error is located, correspond to said first remainder pattern.

3. The error correction circuit in accordance with claim 2, wherein said error location detector includes a plurality of logical circuits for detecting patterns corresponding to the second remainder patterns according to the second remainder patterns to output detection signals; and
said logical circuits set the detection signals to binary 1 or 0 on detecting a corresponding pattern or on not detecting a corresponding pattern, respectively.

4. The error corrector in accordance with claim 3, wherein said error bit correction circuit includes a plurality of exclusive OR circuits executing exclusive OR operations on the detection signals output from said logical circuits and bits of the received codeword for each bit of the received codeword.
